(19) United States
(12) Patent Application Publication
(10) Pub. No.: US 2013/0134283 A1
(43) Pub. Date: May 30, 2013

(54) COVER PANEL CAPABLE OF KEEPING DISPLAY PANEL DIAGONALLY

(71) Applicant: Shouichi Tanaka, (US)

(72) Inventor: Shouichi Tanaka, (US)

(21) Appl. No.: 13/305,806

(22) Filed: Nov. 29, 2011

(51) Int. Cl. H05K 7/00; A47B 97/00; F16M 13/02

(52) U.S. Cl. 248/451; 248/205.1

(57) ABSTRACT

It is an object of the present invention to provide a cover panel for keeping a display panel diagonally. A cover panel is employed by an information-indicating means, for example a paper folder, a paper binder, a book with a hard cover and an electronic display. The cover panel is connected to a display panel with a main joint portion. The cover panel is divided into an upper portion and a lower portion by a sub joint portion. When cover panel is opened, the swung lower portion extends on a desk top. In another case, the lower portion and the sub joint portion is abbreviated.

### BACKGROUND OF THE INVENTION

1. Field of the Invention

The present invention is related to a cover panel for keeping a display panel diagonally, and more particularly to a cover panel serving as a panel stand.

2. Description of the Related Art

It is suitable for a paper, a book or an electronic display to keep a display surface diagonally. The book includes a novel, a picture book and a cooking book. Generally, a paper stand or a book stand is used for keeping a paper or a book diagonally. For example, U.S. Pat. No. 4,555,128 proposes a paper stand. However, prior paper stands are inconvenient for handling and carrying, and they occupy a desk top.

### CITATION LIST

### Patent Literature

[PTL 1] U.S. Pat. No. 4,555,128

### SUMMARY OF THE INVENTION

It is an object of the present invention to provide a cover panel for keeping a display panel diagonally. It is another object of the present invention to provide a handy stand consisting of a cover panel. The cover panel of the invention can be employed by an information panel, for example a paper folder, a paper binder, a book. Further, a smart phone and a tablet computer with an electronic display can employ the cover panel of the invention.

A cover panel of the present invention is connected (engaged) to a display panel with a main joint portion. The cover panel for protecting a display surface of the display panel is swung around the main joint portion for viewing. The cover panel is divided into an upper portion and a lower portion. They are connected (engaged) to each other by a sub joint portion. The lower portion is swung, when the display panel is mounted on a desk top diagonally. It is suitable that the upper portion extends in a right angle for the display panel.

The lower portion of the cover panel extends along the desk top, when the display panel is standing on the desk top diagonally. The lower portion of the cover panel can be abbreviated, if incomplete protection of the display panel is permitted. The cover panel for covering and protecting the display panel can support the display panel standing on the desk top diagonally. A user does not need to handle or carry a traditional stand in order to keep a diagonal posture of the display panel.

According to a preferred embodiment, the cover panel has a second sub joint portion extending in parallel to the main joint portion extending straightly between the cover panel and the display panel. The cover panel is divided into four pieces connected (engaged) to each other by two sub joint portions. Accordingly, the display panel can have two diagonal postures.

### BRIEF DESCRIPTION OF THE DRAWINGS

FIG. 1 is a schematic perspective view of a standing paper folder with a back cover (a back panel) and a front cover (a cover panel).

FIG. 2 is an elevation showing the opened shape of the paper folder.

FIG. 3 is a plan view showing the opened paper folder shown in FIG. 2.

FIG. 4 is a plan view showing the standing paper folder shown in FIG. 1.

FIG. 5 is an elevation showing the closed shape of the paper folder.

FIG. 6 is a side view showing the standing paper folder shown in FIG. 1.

FIG. 7 is an elevation showing the standing paper folder shown in FIG. 1.

FIG. 8 is a schematic elevation showing the opened shape of a book with a hard cover including a rigid back cover and a rigid front cover.

FIG. 9 is a schematic elevation showing the opened shape of another paper folder having rigid back cover and rigid front cover.

FIG. 10 is a schematic elevation showing the opened shape of another paper folder with a paper.

FIG. 11 is a schematic elevation showing the opened shape of the paper-less paper folder shown in FIG. 10.

FIG. 12 is a schematic elevation showing the opened shape of a handy computer of tablet type.

FIG. 13 is a side view showing the handy computer shown in FIG. 12.

FIG. 14 is a perspective view showing another paper folder.

FIG. 15 is an elevation showing the standing posture of the paper folder shown in FIG. 14.

### DETAILED DESCRIPTION OF PREFERRED EMBODIMENTS

### First Embodiment

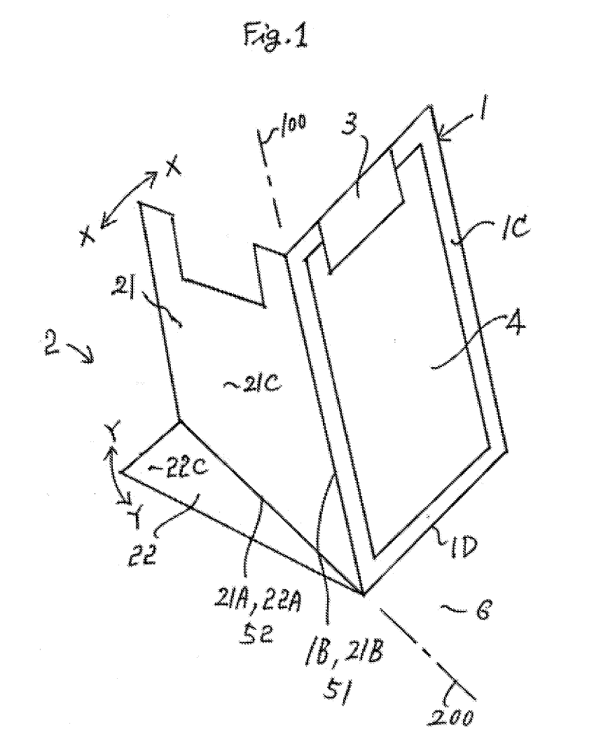

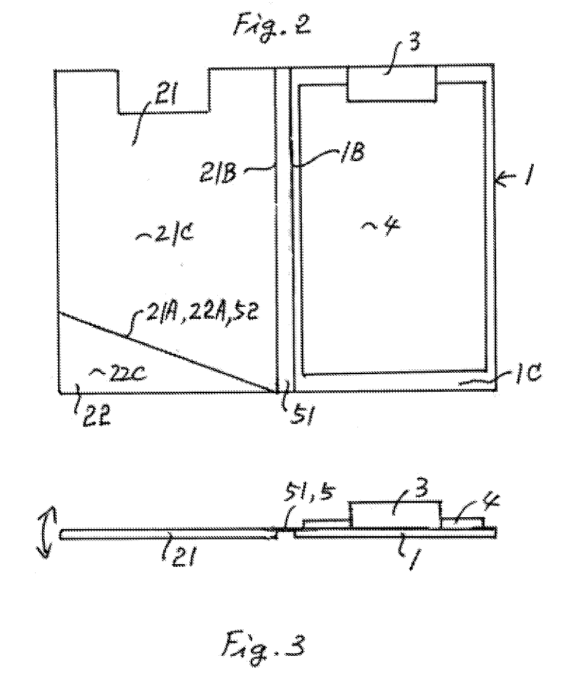

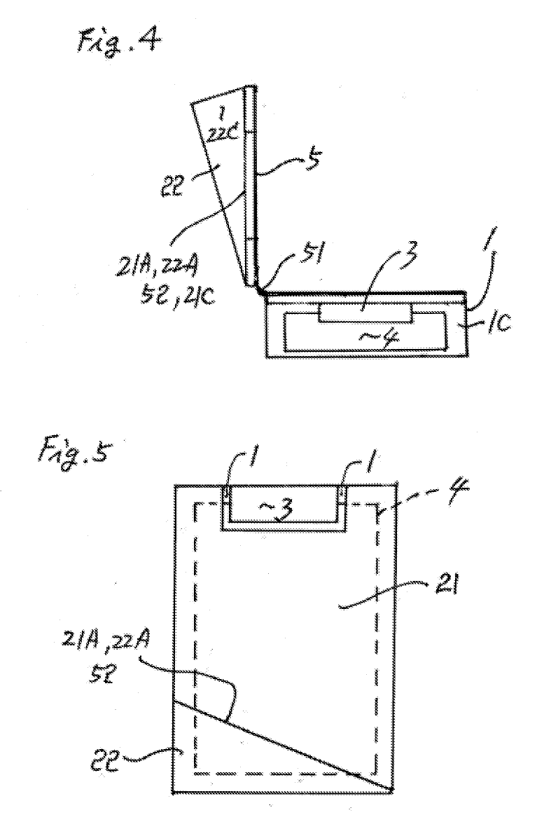

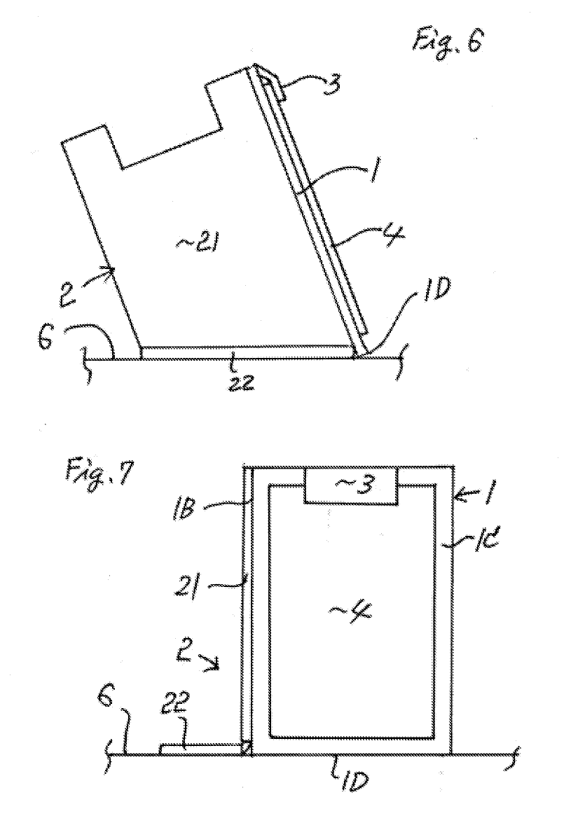

The first embodiment is explained referring to FIGS. 1-7. FIG. 1 is a perspective view of a standing paper folder with a back cover (display panel) 1 and a front cover (cover panel) 2. FIG. 2 is an elevation showing opened shape of the paper folder. FIG. 3 is a plan view showing the opened paper folder shown in FIG. 2. FIG. 4 is a plan view showing the standing paper folder shown in FIG. 1. FIG. 5 is an elevation showing closed shape of the paper folder. FIG. 6 is a side view showing the standing paper folder shown in FIG. 1. FIG. 7 is an elevation showing the standing paper folder shown in FIG. 1.

The back cover 1 has a clamp (paper keeper) clamping a paper 4. The rigid back cover 1 is made with a thick paper board or a plastic plate with predetermined thickness. The clamp 3 fixed on the top portion of back cover 1 has a spring member for the clamping. Clamp 3 is formed with plastic members or metal members. Any type of clamp mechanism can be employed. The paper 4 is mounted on an inner surface 1C of back cover 1 by clamp 3.

The rigid front cover 2 is made with a thick paper board or a plastic plate with predetermined thickness. Front cover 2 has a trapezoid upper portion 21 and a right-angled triangle lower portion 22, which are separated to each other. When the portions 21 and 22 extend along the same direction, front cover 2 has essentially same shape as the rectangular back cover 1.

A lower edge 21A of upper portion 21 is adjacent to an upper edge 22A of lower portion 22. Further, a right edge 21B of upper portion 21 is adjacent to a left edge 1B of back cover 1. FIG. 1 shows an inner surface 21C of upper portion 21, an inner surface 22C of lower portion 22 and the inner surface 1C of back cover 1. A plastic cover sheet 5 (not shown in FIG. 1) is adhered on both of inner surfaces 21C, 22C and 1C and outer surfaces of back cover 1 and front cover 2. It is capable that the plastic cover sheet 5 is adhered on either one of the inner surfaces 21C, 22C and 1C and the outer surfaces of back cover 1 and front cover 2.

The plastic cover sheet 5 forms a main joint portion 51 and a sub joint portion 52. The main joint portion 51 consists of a linear portion of plastic cover sheet 5. Main joint portion 51 extending straightly is adjacent to the right edge 21B of upper portion 21 and the left edge 1B of back cover 1. The sub joint portion 52 consists of a linear portion of plastic cover sheet 5 extending diagonally. Sub joint portion 52 is adjacent to the lower edge 21A of upper portion 21 and the upper edge 22A of lower portion 22.

Upper portion 21 of front cover 2 is capable of swinging (turning) around edges 21B and 1A. Similarly, lower portion 22 of front cover 2 is capable of swinging (turning) around edges 21A and 22A. In the other words, upper portion 21 is capable of swinging to the direction X-X around a virtual axis 100 extending along main joint portion 51. Similarly, lower portion 22 is capable of swinging to the direction Y-Y around a virtual axis 200 extending along sub joint portion 52. After all, plastic cover sheet 5 constitutes two hinges formed along edges 1B, 21B, 21A and 22A. After all, back cover 1, upper portion 21 and lower portion 22 are adhesively engaged with plastic cover sheet 5. Any hinge mechanism can be employed instead of plastic cover sheet 5.

In FIG. 1, a lower edge 1D of back cover 1 is on a flat desk top 6. The outer surface of lower portion 22 is on the flat desk top 6. An angle between upper portion 21 of front panel 2 and back cover 1 is about 90 degrees. An angle between upper portion 21 and lower portion 22 is about 90 degrees. Consequently, the paper folder stands on flat desk top 6 diagonally. Paper 4 extends diagonally on back panel 1. It is capable to employ a spine between two edges 1B and 21B. The spine can be formed from plastic cover sheet 5, if plastic cover sheet 5 has a predetermined linear gap between adjacent two edges 1B and 21B.

### Second Embodiment

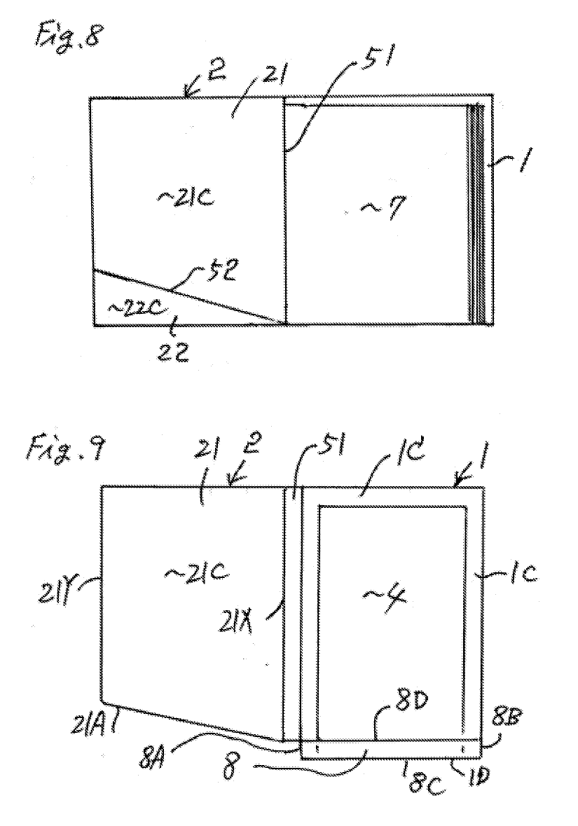

The second embodiment is explained referring to FIG. 8. FIG. 8 is a schematic elevation showing an opened book with a hard cover including a back cover 1 and a front cover 2. The book has many paper sheets 7. Structure of the rigid back cover 1 and the rigid front cover 2 has essentially same shape as back cover 1 and front cover 2 of the paper folder shown in FIGS. 1-7.

### Third Embodiment

The third embodiment is explained referring to FIG. 9. FIG. 9 is a schematic elevation showing another example of opened paper folder with rigid back cover 1 and rigid front cover 2. The paper folder shown in FIG. 9 is essentially same as the paper folder shown in FIGS. 1-7. However, the paper folder shown in FIG. 9 does not have the lower portion 22 and the sub joint portion 52.

Instead of the lower portion 22, the paper folder shown in FIG. 9 has a belt-shaped paper-keeping portion (paper keeper) made of a thick paper board. The paper-keeping portion 8 is fixed on a lower portion of inner surface 1C of back cover 1. A lower edge 8C of paper-keeping portion 8 is adhered to the lower edge 1D of back cover 1. Further, one or both of side edges 8A and 8B of paper-keeping portion 8 is adhered to one or both of side edges of back cover 1.

An upper edge 8D of paper-keeping portion 8 is not adhered to inner surface 1C of back cover 1. Paper 4 is inserted in a pocket formed between paper-keeping portion 8 and back cover 1. Upper portion 21 of front cover 2 is not overlying paper-keeping portion 8. Accordingly, the paper folder has an essentially constant thickness by means of abbreviating the lower portion 22. Front cover 2 has a lower edge 21A extending diagonally. An inner side edge 21X of front cover 2 is longer than an outer side edge 21Y of front cover 2.

### Fourth Embodiment

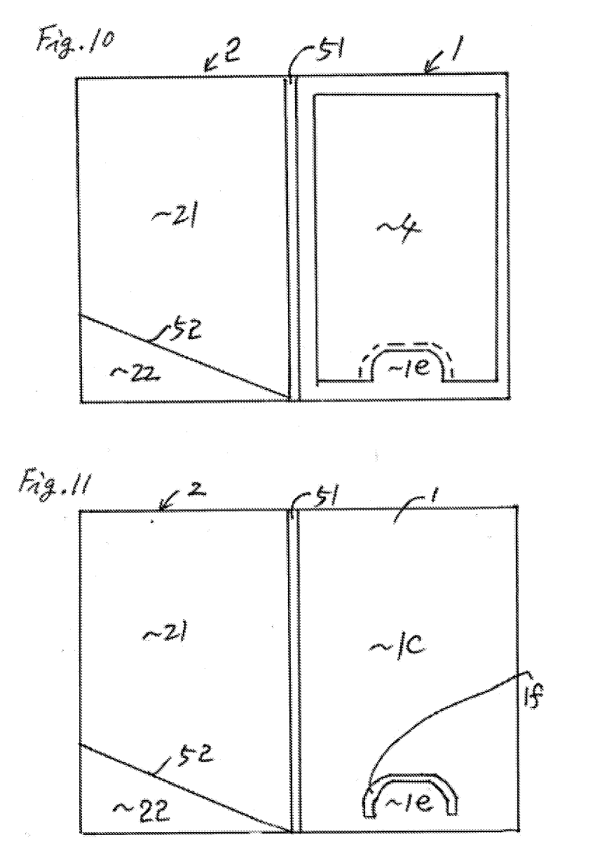

The fourth embodiment is explained referring to FIGS. 10 and 11. FIGS. 10 and 11 are schematic elevations showing another example of an opened paper folder. The paper folder shown in FIG. 10 holds paper 4, but the paper folder shown in FIG. 11 does not hold paper 4. The paper folder shown in FIGS. 10 and 11 has a paper-keeping portion (paper keeper) 1e made of back cover 1. The paper-keeping portion 1e is formed by means of forming a U-character-shaped trench 1f at a lower portion of back cover 1. As shown in FIG. 10, a lower portion of paper 4 is inserted into the U-character-shaped trench if. Accordingly, paper 4 is mounted by back cover 1.

### Fifth Embodiment

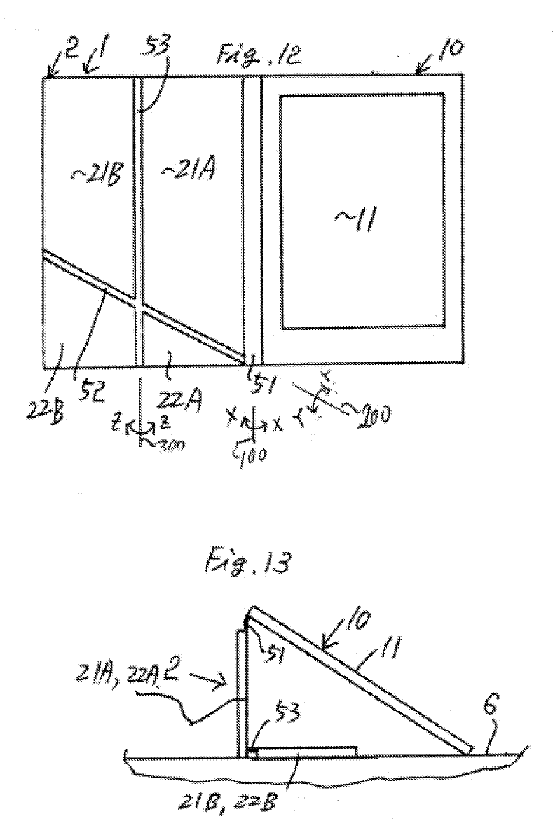

The fifth embodiment is explained referring to FIGS. 12 and 13. FIG. 12 is a schematic elevation showing an opened handy computer 10 of tablet type. FIG. 13 shows tablet computer 10 standing diagonally. The tablet computer 10 has a flat display 11. Front cover (cover panel) 2 further has a second sub joint portion 53 extending in parallel to main joint portion 51.

Accordingly, the second sub joint portion 53 divides upper portion 21 into an inner portion 21A and an outer portion 21B. Furthermore, the second sub joint portion 53 divides lower portion 22 into an inner portion 22A and an outer portion 22B. The outer portions 21B and 22B are capable of swinging together to the direction Z-Z around a virtual axis 300 extending along the second sub joint portion 53. Tablet computer 10 has a lengthwise posture, when lower portions 22A and 22B are swung.

### Sixth Embodiment

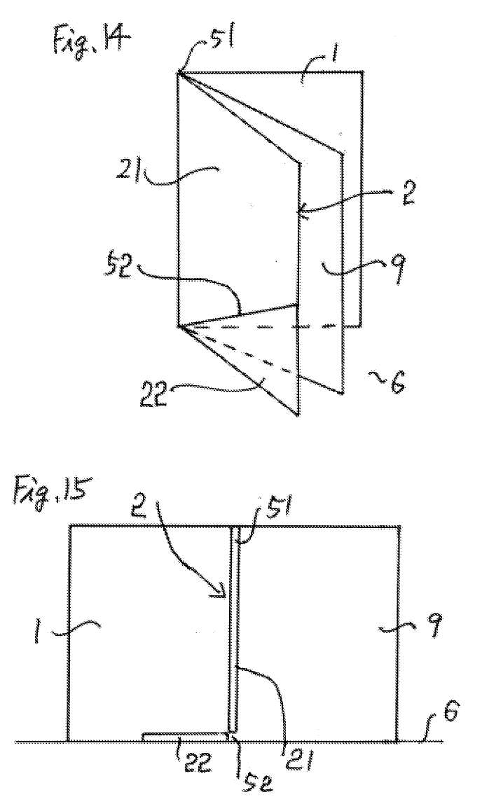

The sixth embodiment is explained referring to FIGS. 14 and 15. FIG. 14 is a perspective view showing another paper folder. FIG. 15 is an elevation showing a standing posture of the paper folder. In FIG. 14, the paper folder is partially opened. In FIG. 15, the paper folder is completely opened.

The rigid paper folder has back cover 1, front cover 2 and central cover 9, which have essentially same sizes each. Except the central cover 9, the paper folder shown in FIGS. 14 and 15 are same as the paper folder shown in FIGS. 1-7. The central cover 9 is added between front cover (cover panel) 2 and back cover (display panel) 1. Central cover 9 has a second display surface. Accordingly, the paper folder can have the wide display surface.

1. A cover panel for keeping a display panel (1) diagonally, the cover panel (2) connected to the display panel (1) by a main joint portion (51) capable of swinging the cover panel (2), wherein:
the cover panel (2) has an upper portion (21), a lower portion (22) and a sub joint portion (52);
the sub joint portion connecting the upper portion (21) to the lower portion (22) is capable of swinging the lower portion (22); and
the cover panel (2) is capable of extending along a desk top (6) in order to stand the display panel (1) diagonally on the desk top (6).

2. The cover panel according to claim 1, wherein:
shape of the upper portion (21) of the cover panel (2) is essentially trapezoid;
shape of the lower portion (22) of the cover panel (2) is essentially right-angled triangle; and
the sub joint portion (52) connects an upper edge (22A) of the lower portion (22) to a lower edge (21A) of the upper portion (21).

3. The cover panel according to claim 1, wherein the cover panel (2) consists of a front cover of a paper folder having a back cover as the display panel (1).

4. The cover panel according to claim 3, wherein the back cover has a paper keeper (3, 8 and 1e) for keeping a paper (4).

5. The cover panel according to claim 1, wherein the cover panel (2) consists of a front cover of a book.

6. The cover panel according to claim 1, wherein the cover panel (2) is engaged with a tablet computer (10).

7. The cover panel according to claim 6, wherein the cover panel (2) has a second sub joint portion (53) extending in parallel to the main joint portion (51) extending straightly between the electronic equipment (10) and the cover panel (2);
the second sub joint portion (53) divides the upper portion (21) into an inner portion (21A) and an outer portion (22B); and
the second sub joint portion (53) further divides the lower portion (22) into an inner portion (22A) and an outer portion (22B);

8. A cover panel for keeping a display panel (1) diagonally, the cover panel (2) connected to the display panel (1) by a main joint portion (51) capable of swinging the cover panel (2), wherein: the cover panel (2) consists of a front cover of a paper folder having a back cover as the display panel (1);
the cover panel (2) has a lower edge (21A) extending diagonally; and
an inner side edge (21X) of the cover panel (2) is longer than an outer side edge (21Y) of the cover panel (2).
